(19) United States
(12) Patent Application Publication
(10) Pub. No.: US 2016/0309599 A1
(43) Pub. Date: Oct. 20, 2016

(54) ORGANIC EL DISPLAY DEVICE, SUPPORT STAND, AND IMAGE DISPLAY DEVICE

(71) Applicant: JOLED INC., Tokyo (JP)

(72) Inventor: Tsutomu KIKUCHI, Hokkaido (JP)

(73) Assignee: JOLED INC., Tokyo (JP)

(21) Appl. No.: 15/101,986

(22) PCT Filed: Apr. 22, 2014
(86) PCT No.: PCT/JP2014/002258

§ 371 Date: Jun. 6, 2016

(30) Foreign Application Priority Data
Dec. 9, 2013 (JP) 2013-254419

(51) Int. Cl. H05K 5/00; H05K 5/02; H05K 5/03; H04N 5/645

(52) U.S. Cl. CPC H05K 5/0017; H04N 5/645; H05K 5/0234; H05K 5/03

(57) ABSTRACT

An organic EL panel unit includes: an organic EL panel that displays an image on a front surface of the organic EL panel; and a chassis that is disposed on a rear surface side of the organic EL panel and holds the organic EL panel. The chassis includes a protrusion that protrudes away from the organic EL panel, and the protrusion has a through-hole formed therethrough.

### TECHNICAL FIELD

The present disclosure relates to an organic electroluminescent (EL) display device including an organic EL panel.

### BACKGROUND ART

Image display devices, such as televisions, include a display panel unit that includes a display panel such as an organic electroluminescent (EL) panel. Inspection for quality verification, for example, is performed before the display panel unit is installed in the enclosure of the image display device, such as a television. Upon inspection, the display panel unit is required to be supported in a standing state on the work table.

For example, Patent Literature (PTL) 1 discloses a support device that supports a flat display panel. According to PTL 1, in the support device including: a support stand; and a stand column that stands upright on the support stand and supports an object to be supported, an insulating spacer, for example, is interposed between the stand column and the support stand. According to this configuration, the support device can be prevented from resonating at a specific frequency.

### CITATION LIST

### Patent Literature

[PTL 1] Japanese Unexamined Patent Application Publication No. 2003-174600

### SUMMARY OF INVENTION

### Technical Problem

The present disclosure provides, for example, an organic EL display device that is easily supported in a standing state and capable of being made thin.

### Solution to Problem

An organic EL display device according to the present disclosure includes: an organic EL panel that displays an image on a front surface of the organic EL panel; and a chassis that is disposed on a rear surface side of the organic EL panel and holds the organic EL panel. The chassis includes a protrusion that protrudes away from the organic EL panel, and the protrusion has a through-hole formed therethrough.

Moreover, a support stand according to the present disclosure supports the above-described organic EL display device in a standing state, and includes: a base; a column standing on the base; and a support component extending from the column in a direction intersecting a lengthwise direction of the column. The support component has an engaging part on a distal end opposite an end at the column. The engaging part engages with an edge of the through-hole in a state in which the engaging part is inserted in the through-hole.

Moreover, an image display device according to the present disclosure includes the above-described organic EL display device and a back cover disposed on a rear surface side of the organic EL display device.

### Advantageous Effects of Invention

The organic EL display device according to the present disclosure is easily supported in a standing state and capable of being made thin. Accordingly, the manufacturing efficiency, for example, of a thin image display device such as a television can be increased.

### BRIEF DESCRIPTION OF DRAWINGS

FIG. 1 is an external perspective view of an image display device according to an embodiment.

FIG. 2 is an exploded perspective view of an image display device according to an embodiment.

FIG. 3 is a plan view schematically illustrating the regions of steps in a chassis according to an embodiment.

FIG. 4 is a partial cutaway perspective view of an organic EL panel according to an embodiment.

FIG. 5 is a perspective view of an example of pixel banks of an organic EL panel according to an embodiment.

FIG. 6 is an electrical diagram illustrating a configuration of pixel circuits in an organic EL panel according to an embodiment.

FIG. 7 is an external perspective view of an organic EL panel unit according to an embodiment.

FIG. 8 is an external perspective view illustrating one example of a configuration of a support stand according to an embodiment.

FIG. 9 illustrates the relationship between sizes and shapes of a through-hole and a support component.

FIG. 10 is a partial cross sectional view of a support component inserted in and engaging with a through-hole.

FIG. 11 is a perspective view of an organic EL panel unit while supported by a support stand.

FIG. 12 illustrates the relationship between sizes and shapes of a through-hole and a support component according to Variation 1 of an embodiment.

FIG. 13 illustrates the relationship between sizes and shapes of a through-hole and a support component according to Variation 2 of an embodiment.

FIG. 14 illustrates the relationship between sizes and shapes of a through-hole and a support component according to Variation 3 of an embodiment.

FIG. 15 is a partial cross sectional view of a support component inserted in and engaging with a through-hole according to Variation 4 of an embodiment.

FIG. 16 is a general external perspective view of a protrusion according to Variation 5 of an embodiment.

FIG. 17 illustrates one example of a positional arrangement of through-holes when a chassis includes two through-holes.

FIG. 18 illustrates one example of a positional arrangement of through-holes when a chassis includes three through-holes.

### DESCRIPTION OF EMBODIMENTS

The inventor has discovered the following problems related to conventional organic EL display devices.

An organic EL panel is a self-luminous display panel, and has a thickness of about 1 mm to 3 mm. Moreover, since there is a demand for making thin image display devices that include organic EL panels, such as televisions, making thin organic EL panel units (organic EL display devices) including an organic EL panel and a chassis is also in demand.

As such, in the process for, for example, inspecting the organic EL display device, stably supporting an entire large-screen, thin organic EL display device while in a standing state requires ingenuity.

However, when the above-described conventional support device, for example, is employed as a device to support the organic EL display device a standing bolt for the support device to support the chassis is required at the lower portion of the chassis. Providing such a bolt that stands on the chassis is not preferable from the perspective of achieving a thin organic EL display device.

Moreover, with such a support device, since the organic EL display device is supported by fixing the lower portion of the organic EL display device, the larger the screen size of organic EL display device and the thinner the organic EL display device, the harder it is to stably support the organic EL display device.

The present disclosure has been conceived based on this knowledge, and as a result of diligent examination, the inventor has arrived at a concept for the structure of an organic EL display device that is easily supported in a standing state and capable of being made thin.

Hereinafter, an embodiment will be described with reference to the drawings appropriately. However, unnecessarily detailed descriptions may be omitted. For example, detailed description of well known matter or repeated description of essentially similar elements may be omitted. This is to avoid unnecessary redundancy and provide easily read descriptions for those skilled in the art.

Note that the inventor has provided the accompanying drawings and following description in order to facilitate sufficient understanding for those skilled in the art, and as such, are not intended to limit the scope of the claims.

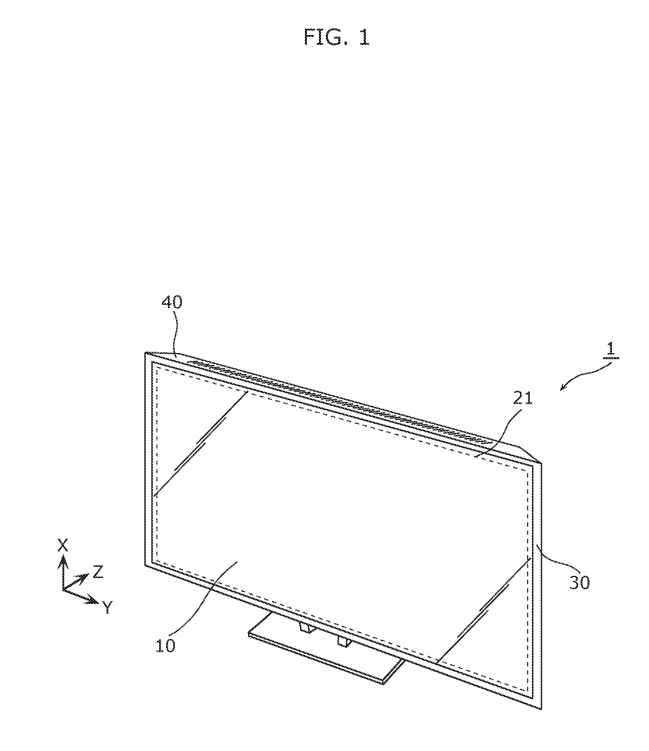

Hereinafter, an embodiment and variations will be described using FIG. 1 through FIG. 16. First, using FIG. 1 through FIG. 3, an outline of the configuration of the image display device according to the embodiment will be given.

### [1-1. Image Display Device Configuration Outline]

FIG. 1 is an external perspective view of an image display device 1 according to the embodiment.

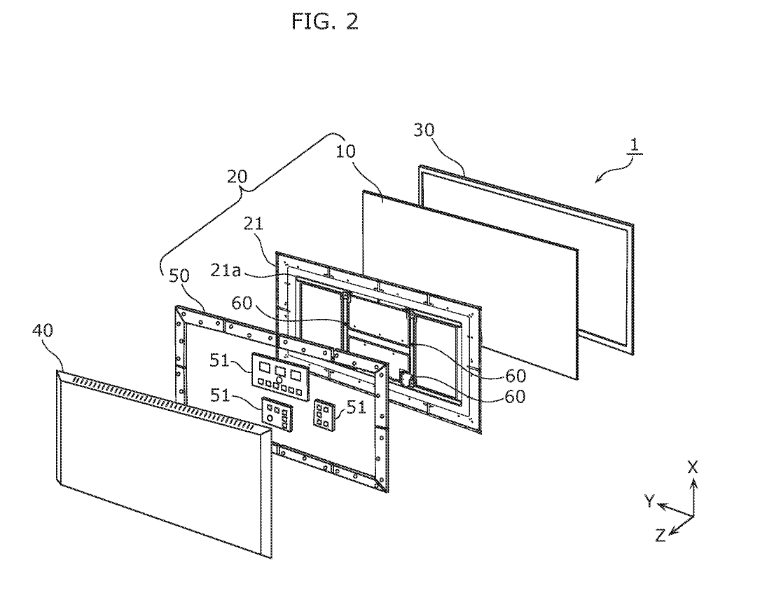

FIG. 2 is an exploded perspective view of the image display device 1 according to the embodiment.

As illustrated in FIG. 1 and FIG. 2, the image display device 1 according to this embodiment includes an organic EL panel unit 20 and a back cover (rear surface enclosure) 40 disposed on the rear surface side of the organic EL panel unit 20.

The organic EL panel unit 20 is one example of the organic EL display device, and includes an organic EL panel 10 that displays images on its front surface, and a chassis 21 that is disposed on the rear surface side of the organic EL panel 10 and holds the organic EL panel 10.

The image display device 1 further includes a frame (frame body) 30 that has the form of a rectangular frame and covers a peripheral edge of the display side surface (front surface) of the organic EL panel 10. The frame 30 and the back cover 40 are formed using a resin material or a metal material, for example.

The image display device 1 is structured such that the organic EL panel unit 20 is disposed between the frame 30 and the back cover 40. Such an image display device 1 may be realized as a television receiver (television) that outputs an image signal and an audio signal which are obtained from received broadcast waves, for example.

Moreover, as illustrated in FIG. 2, a plurality of circuit substrates 50 are attached to the rear surface of the chassis 21. The circuit substrates 50 are drive circuit substrates provided with a drive circuit (driver) that supplies a signal voltage to the organic EL panel 10. The plurality of circuit substrates 50 are disposed along the peripheral edge of the chassis 21 and are connected to the organic EL panel 10 via a flexible cable.

Moreover, a plurality of circuit substrates 51 are attached to the rear surface of the chassis 21, in a predetermined region including the central region. The electronic circuits included in the circuit substrates 51 include, for example, a signal processing circuit that processes received image signals, a control circuit that controls operations performed by a scan drive circuit and signal line drive circuit, and a power supply circuit that supplies, to each circuit, power received from an external source.

Note that the image display device 1 includes other elements not shown in FIG. 2, such as the flexible cable that connects the circuit substrates 50 and the organic EL panel 10, but depiction of these elements in the drawings and description thereof are omitted in order to demonstrate the characteristics of the image display device 1 according to the present disclosure.

The chassis 21 is, for example, a metal component, and includes a protrusion 21a that protrudes away from the organic EL panel 10 and has a through-hole 60 formed therethrough. In other words, the chassis 21 has, simply stated, the form of a flat plate-shaped main body having the protrusion 21a formed therein.

The chassis 21 according to this embodiment is a component formed by carrying out a stamping process, such as a drawing process, on a rectangular metal plate component (metal plate) made of, for example, aluminum or steel, to form the protrusion 21a.

For example, the protrusion 21a can be formed by processing an aluminum plate having a thickness of 0.6 mm with a drawing process. By forming the protrusion 21a (drawn portion) in this way, the rigidity of the chassis 21 can be increased.

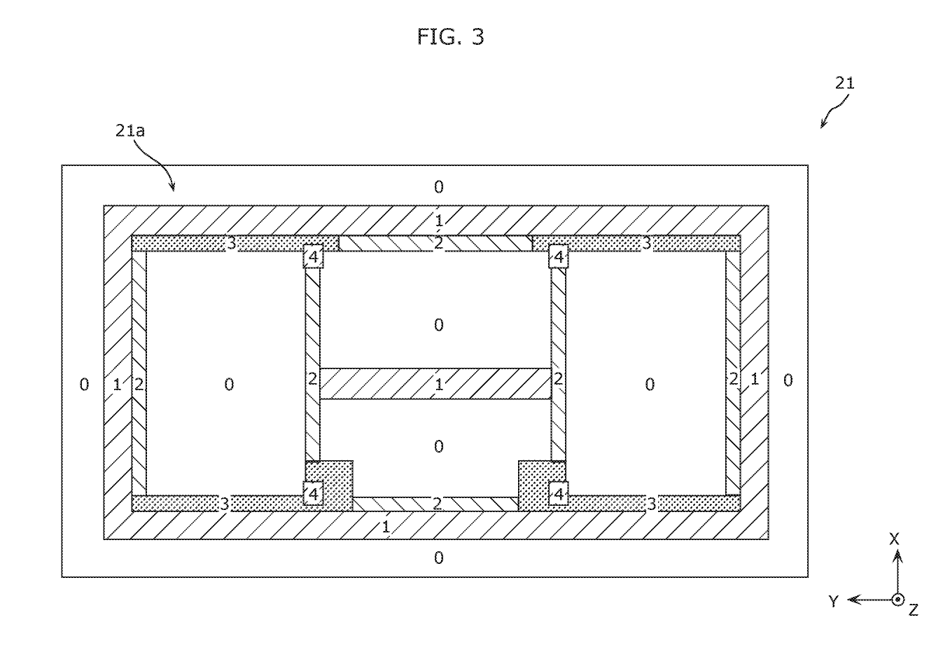

Note that in this embodiment, the protrusion 21a is drawn in four steps, as illustrated in FIG. 3. In other words, the protrusion 21a has four tiers of heights.

FIG. 3 is a plan view schematically illustrating the regions of steps in the chassis 21 according to this embodiment.

In FIG. 3, each region labeled with numerals 0 through 4 indicates the height position of the step (position of the protrusion 21a in the protrusion direction (positive Z axis direction)), and regions of the same step height position are indicated with the same style of hatching.

More specifically, the regions labeled 0 are regions acting as a reference surface in which drawing processing has not be performed. Regions labeled as 0 are regions closest to the organic EL panel 10, and are sections which contact or are connected to the organic EL panel 10.

Moreover, regions labeled as 1 are regions one step higher than the reference surface, and regions labeled as 2 are regions two steps higher than the reference surface. Moreover, regions labeled as 3 are regions three steps higher than the reference surface, and regions labeled as 4 are regions four steps higher than the reference surface.

Note that in this embodiment, while the protrusion 21a included in chassis 21 is formed by a drawing process so as to include a plurality of steps as described above, the protrusion 21a may have the same height throughout. In other words, protrusion 21a need not include a plurality of steps.

Moreover, the through-hole 60 is formed in the protrusion 21a included in the chassis 21 according to this embodiment. The through-hole 60 is formed, for example, along with the protrusion 21a in the same stamping process used to form the protrusion 21a. Note that the timing at which the through-hole 60 is formed may be before or after stamping process for forming the protrusion 21a.

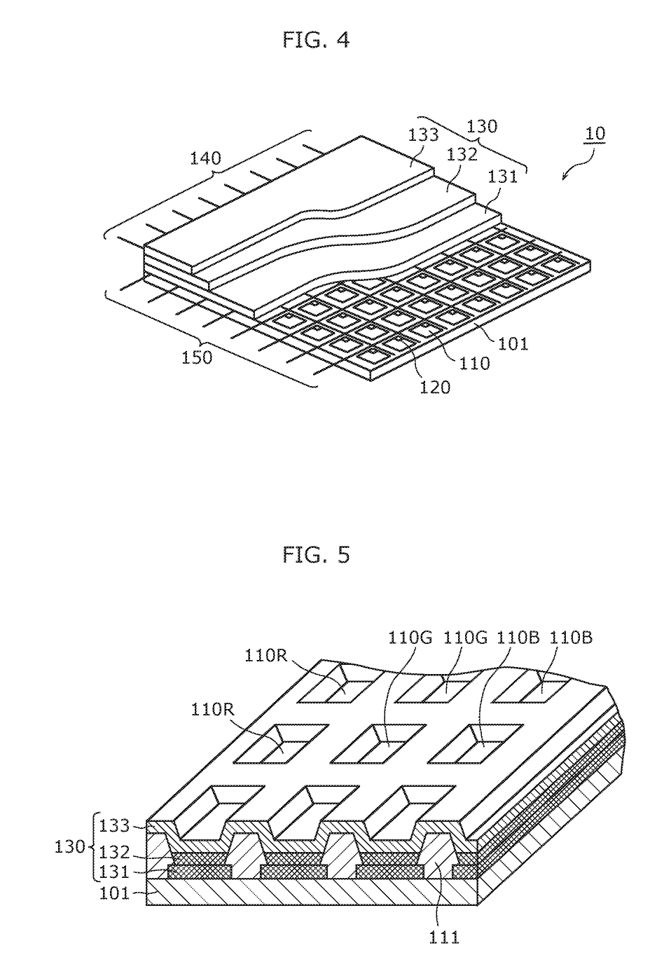

Next, the organic EL panel unit 20 included in the image display device 1 described above will be described using FIG. 4 through FIG. 11. First, using FIG. 4 through FIG. 6, a general outline of the configuration of the organic EL panel 10 included in the organic EL panel unit 20 according to the embodiment will be given.

### [1-2. Organic EL Panel]

FIG. 4 is a partial cutaway perspective view of the organic EL panel 10 according to this embodiment.

FIG. 5 is a perspective view of pixel banks of the organic EL panel 10 according to this embodiment.

As illustrated in FIG. 4, the organic EL panel 10 has a stacked structure including: a TFT substrate (TFT array substrate) 101 on which a plurality of thin-film transistors are arranged; and organic EL elements (light-emitting units) 130. The organic EL element 130 includes an anode 131, which is a lower electrode, an EL layer 132, which is a light-emitting layer made of an organic material, and a cathode 133, which is an upper electrode.

Note that although it is omitted from FIG. 4 and FIG. 5, the organic EL panel 10 includes a glass substrate disposed above the organic EL elements 130.

Additionally, the TFT substrate 101 has a structure in which various elements, such as the gate electrode, are stacked on a glass substrate. In other words, the organic EL panel 10 has an overall structure in which the organic EL elements 130 and the like are interposed between two glass substrates. The thickness of the organic EL panel 10 having such a structure is, for example, about 1 mm to 3 mm.

A plurality of pixels 110 are arranged in a matrix on TFT substrate 101, and each of the pixels 110 includes a pixel circuit 120.

The organic EL elements 130 are formed in one-to-one correspondence with the plurality of pixels 110, and the pixel circuits 120 of the pixels 110 control light emission of the organic EL elements 130. The organic EL elements 130 are formed on an interlayer insulation film (planarizing film) formed so as to cover the plurality of thin-film transistors.

Moreover, the organic EL elements 130 each have a structure in which the EL layer 132 is disposed between the anode 131 and the cathode 133. A positive hole transport layer is further formed and stacked between the anode 131 and the EL layer 132, and an electron transport layer is further formed and stacked between the EL layer 132 and the cathode 133. Note that another organic functional layer may be provided between the anode 131 and the cathode 133.

The pixel circuits 120 control driving of the pixels 110. In addition, a plurality of gate wires (scanning lines) 140 disposed in the row direction of the pixels 110, a plurality of source wires (signal wires) 150 disposed in the column direction of the pixels 110 so as to intersect the gate wires 140, and a plurality of power supply wires (omitted in FIG. 4) disposed in parallel with the source wires 150 are formed on the TFT substrate 101. The pixels 110 are separated by the gate wires 140 and the source wires 150 disposed orthogonal to one another, for example.

The gate wires 140 are each connected to one row of gate electrodes of thin-film transistors which operate as switching elements included in the pixel circuits 120. The source wires 150 are each connected to one column of source electrodes of thin-film transistors which operate as switching elements included in the pixel circuits 120. The power supply wires are each connected to one column of drain electrodes of thin-film transistors which operate as driver elements included in the pixel circuits 120.

As illustrated in FIG. 5, the pixels 110 of the organic EL panel 10 include three sub pixels 110R, 110G, and 110B of three colors (red, green, and blue). The plurality of sub pixels 110R, 110G, and 110B are disposed in a matrix on the display surface.

The sub pixels 110R, 110G, and 110B are separated from one another by banks 111. The banks 111 are formed to make a lattice such that protruding lines extending in parallel with the gate wires 140 and protruding lines extending in parallel with the source wires 150 intersect one another. Portions surrounded by the protruding lines (in other words, openings of the banks 111) and the sub pixels 110R, 110G, and 110B are in one-to-one correspondence. Note that although the banks 111 are pixel banks in this embodiment, the banks 111 may be line banks.

The anode 131 is formed for each of the sub pixels 110R, 110G, and 110B, on the interlayer insulation film (planarizing film) on the TFT substrate 101 and inside the openings of the banks 111. Similarly, the EL layer 132 is formed for the sub pixels 110R, 110G, and 110B, on the anode 131 and inside the openings of the banks 111. The transparent cathode 133 is formed in a continuous manner above the banks 111 so as to cover the entire EL layer 132 (all the sub pixels 110R, 110G, and 110B).

Furthermore, the pixel circuits 120 are provided in one-to-one correspondence with the sub pixels 110R, 110G, and 110B, and the sub pixels 110R, 110G, and 110B and the pixel circuits 120 in one-to-one correspondence therewith are electrically connected by contact holes and relay electrodes. Note that the sub pixels 110R, 110G, and 110B have the same configurations, except that the color of the light they emit on the EL layer 132 is different.

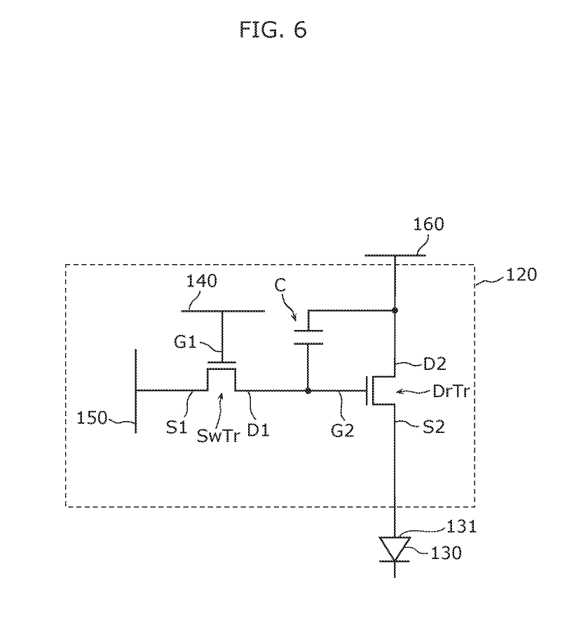

Here, the circuit configuration of the pixel circuits 120 of the pixels 110 will be described with reference to FIG. 6. FIG. 6 is an electrical diagram illustrating the configuration of the pixel circuits 120 in the organic EL panel 10 according to this embodiment.

As illustrated in FIG. 6, each pixel circuit 120 includes a thin-film transistor SwTr, which operates as a switching element, a thin-film transistor DrTr, which operates as a driver element, and a capacitor C, which stores data to be displayed using the corresponding pixel 110. In this embodiment, the thin-film transistor SwTr is a switching transistor for selecting a pixel 110, and the thin-film transistor DrTr is a drive transistor for driving the organic EL element 130.

The thin-film transistor SwTr includes a gate electrode G1 connected to the gate wire 140, a source electrode S1 connected to the source wire 150, a drain electrode D1 connected to the capacitor C and a gate electrode G2 of the thin-film transistor DrTr, and a semiconductor film (not illustrated). If a predetermined voltage is applied to the gate wire 140 and the source wire 150 connected to the thin-film transistor SwTr, the voltage applied to the source wire 150 is stored in the capacitor C as a data voltage.

The thin-film transistor DrTr includes the gate electrode G2 connected to the drain electrode D1 of the thin-film transistor SwTr and the capacitor C, a drain electrode D2 connected to a power supply wire 160 and the capacitor C, a source electrode S2 connected to the anode 131 of the organic EL element 130, and a semiconductor film (not illustrated). The thin-film transistor DrTr supplies, from the power supply wire 160 to the anode 131 of the organic EL element 130 via the source electrode S2, a current corresponding to the data voltage stored in the capacitor C. Accordingly, a drive current flows from the anode 131 to the cathode 133 in the organic EL element 130, causing the EL layer 132 to emit light.

Note that the organic EL panel 10 having the above configuration employs an active matrix scheme for display control of each of the pixels 110 located at the intersections of the gate wires 140 and the source wires 150. With this, the thin-film transistors SwTr and DrTr of each of the pixels 110 (the sub pixels 110R, 110G, and 110B) cause the corresponding organic EL element 130 to selectively emit light, thus displaying a desired image.

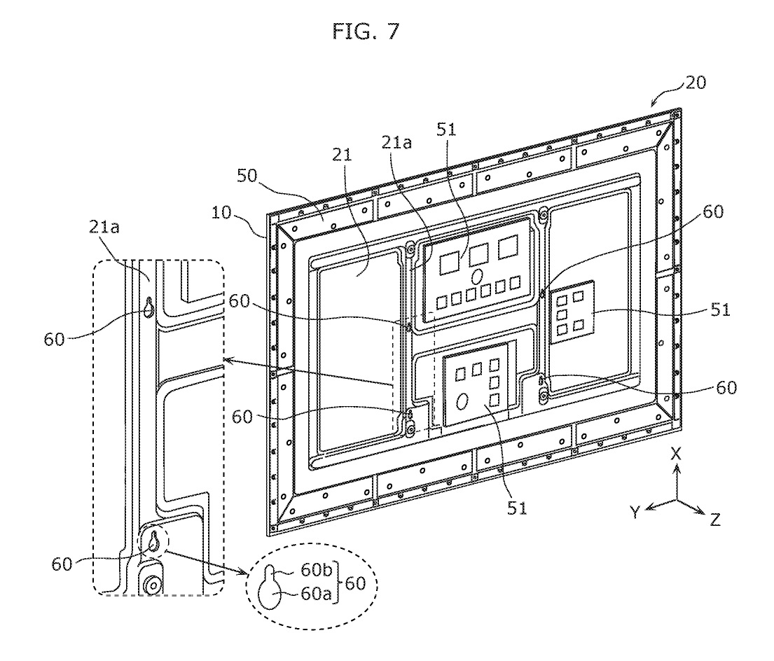

Next, the configuration of the organic EL panel unit 20 and the support stand 200 thereof for supporting the organic EL panel unit 20 in the inspection process for the organic EL panel unit 20 will be described using FIG. 7 through FIG. 11.

### [1-3. Organic EL Panel Unit]

FIG. 7 is an external perspective view of the organic EL panel unit 20 according to this embodiment.

Note that in FIG. 7, similar to FIG. 2, elements such as internal wires (flexible cable) and such that essentially do not concern the characteristics of the organic EL panel unit 20 are omitted.

As illustrated in FIG. 7, the chassis 21 of the organic EL panel unit 20 includes the protrusion 21a formed by a drawing process, and the through-hole 60 is formed in the protrusion 21a.

In this embodiment, four through-holes 60 are formed in the protrusion 21a of the chassis 21. Note that in this embodiment, four through-holes 60 are formed in a single protrusion 21a covering a relatively wide region of the chassis 21 (a region spanning the regions labeled 1 through 4 in FIG. 3). However, each through-hole 60 may be provided in a different one of protrusions separated from each other in the chassis 21.

In this embodiment, each through-hole 60 is a hole that penetrates through a portion of the protrusion 21a, in a protruding direction (positive Z axis direction) of the protrusion 21a. Each through-hole 60 is formed to have, in a plan view of the through-hole 60 (i.e., in a view looking at a side of the chassis 21 reverse from the side on which the organic EL panel 10 is disposed; the same applies hereinafter), two ends in opposing locations having mutually different widths (width in a direction perpendicular to a direction connecting the two ends).

More specifically, as illustrated in FIG. 7, among the two ends in a plan view of the through-hole 60, the lower end is greater in width than the upper end. Moreover, among the two ends, the lower end is of a size that allows for insertion and removal of a predetermined component, and the upper end is of a size that causes the upper end to engage the predetermined component inserted via the lower end.

Note that “upper” and “lower” in this embodiment mean upper and lower when the organic EL panel unit 20 is in a standing state upon inspection.

In other words, “upper” and “lower” according to this embodiment may match “upper” and “lower” in a state in which the image display device 1, which includes the organic EL panel unit 20 and is realized as, for example, a television, is installed, and alternatively may not match this definition of “upper” and “lower”.

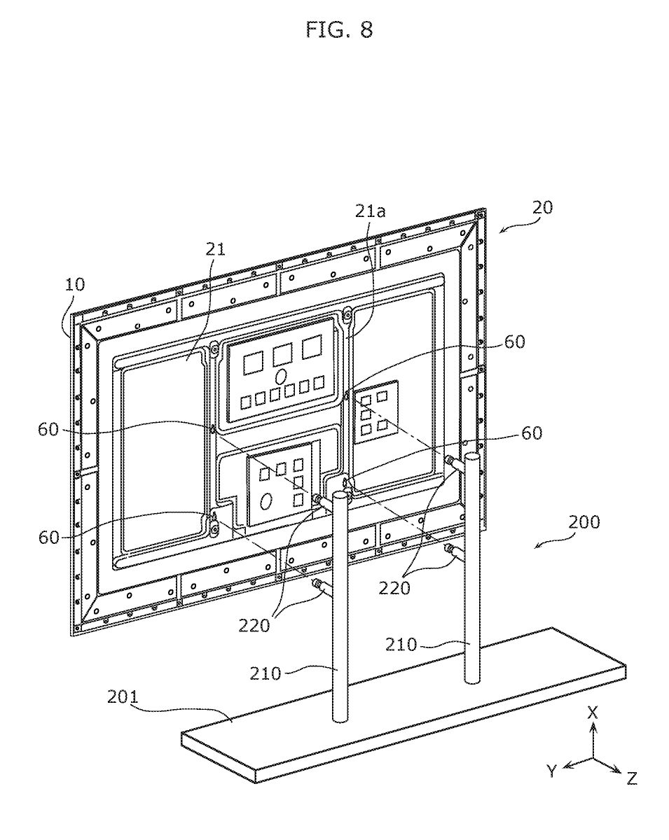

Moreover, the “predetermined component” referred to above is, in this embodiment, a support component 220 included in a support stand 200 to be described later using FIG. 8, and the organic EL panel unit 20 is stably supported while the support component 220 is inserted in the through-hole 60.

In this embodiment, more specifically, the through-hole 60 includes a first hole 60a and a second hole 60b defined by an outwardly extending portion of an edge of the first hole 60a, and the first hole 60a includes the wider end among the two ends, and the second hole 60b includes the narrower end among the two ends.

In other words, the through-hole 60 according to this embodiment is a single hole having the shape of a large hole and a small hole partially overlapping one another—a shape referred to as, for example, a “keyhole” shape.

Moreover, the two upper through-holes 60 among the four through-holes 60 are arranged in the chassis 21 such that a midpoint between the two upper through-holes 60 is located in a widthwise (Y direction) center of the chassis 21. Moreover, similarly, the two lower through-holes 60 among the four through-holes 60 are arranged in the chassis 21 such that a midpoint between the two lower through-holes 60 is located in a widthwise (Y direction) center of the chassis 21.

In this way, the organic EL panel unit 20 including four through-holes 60 formed in the protrusion 21a of the chassis 21 is supported by the support stand 200 in the manner illustrated in FIG. 8.

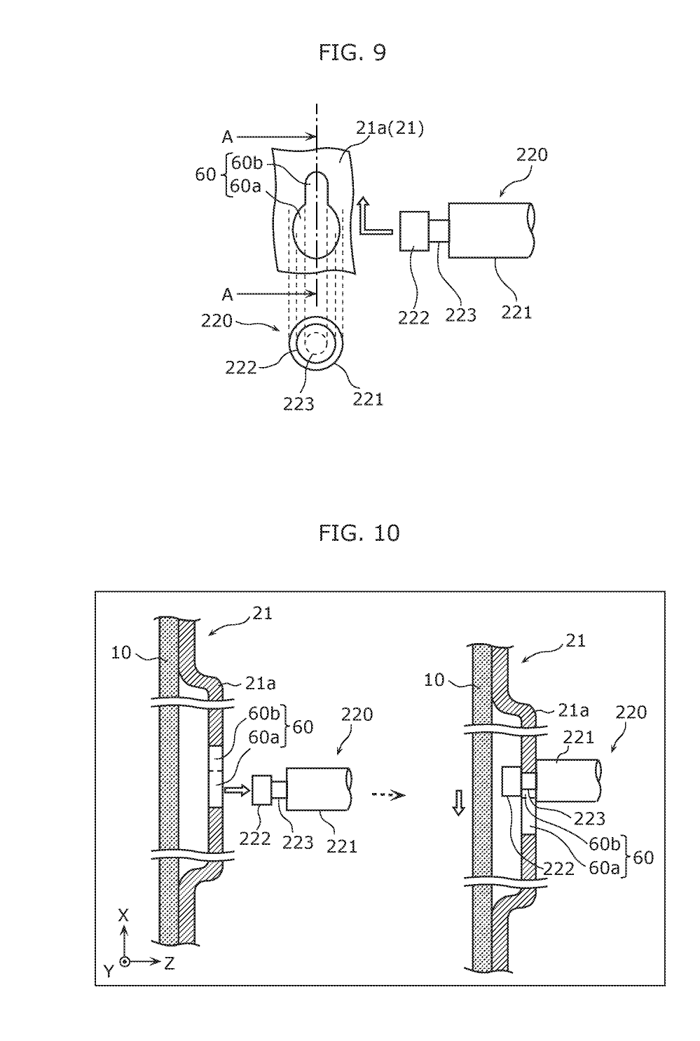

FIG. 8 is an external perspective view illustrating one example of the configuration of the support stand 200 according to this embodiment. FIG. 9 illustrates the relationship between the sizes and shapes of the through-hole 60 and the support component 220.

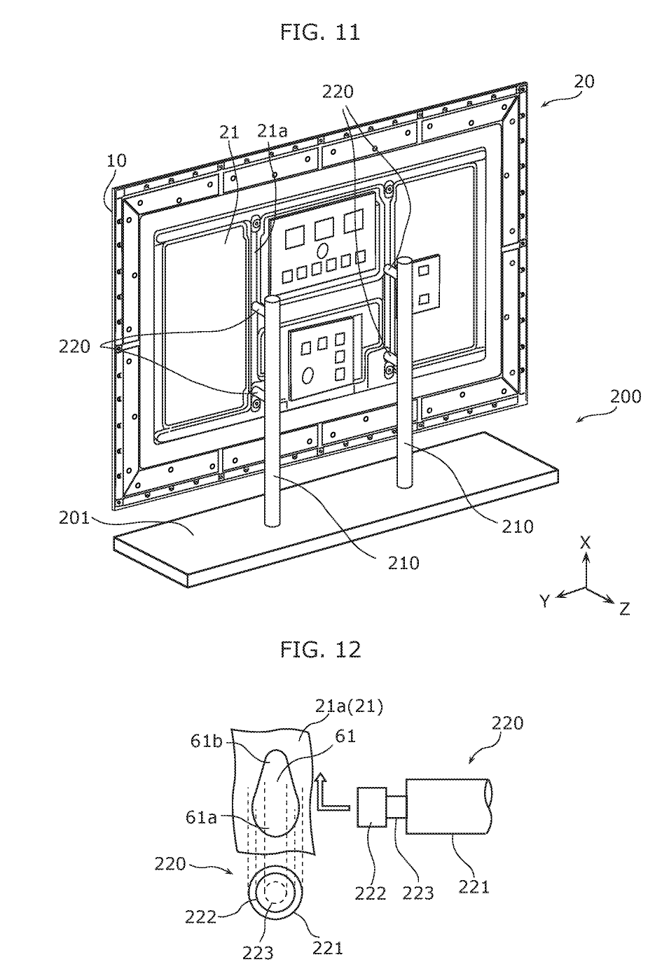

FIG. 10 is a partial cross sectional view of the support component 220 inserted in and engaging with the through-hole 60. FIG. 11 is a perspective view of the organic EL panel unit 20 while supported by the support stand 200.

Note that the cross section of the protrusion 21a illustrated in FIG. 10 is a cross section including a cross section taken along line A-A in FIG. 9. Moreover, in FIG. 10, support component 220 is shown in a side view.

As illustrated in FIG. 8, the support stand 200 according to this embodiment includes a base 201, a column 210 standing on the base 201, and a support component 220 extending from the column 210 in a direction intersecting the lengthwise direction of the column 210.

The support component 220 has an engaging part 222 on an end opposite the column 210, and the engaging part 222 engages with an edge of the through-hole 60 in a state in which the engaging part 222 is inserted in the through-hole 60. More specifically, support component 220 further includes shaft part 221 and small diameter part 223 that connects the shaft part 221 and the engaging part 222. The small diameter part 223 is a part whose diameter is smaller than that of the shaft part 221 and that of the engaging part 222.

The support stand 200 according to this embodiment includes two columns 210 standing on the base 201, and each of the two columns 210 includes two support components 220, as illustrated in FIG. 8.

Note that the method of connecting the columns 210 and the support components 220 together is not particularly limited. For example, when the columns 210 and the support components 220 are made of metal, the columns 210 and the support components 220 may be welded together. Moreover, the columns 210 and the support components 220 may be connected together by forming screw holes (nuts) in the columns 210 and screwing screws provided on the support components 220 on ends opposite the engaging part 222 into the nuts. The same applies to the connection of the base 201 and the columns 210; various methods may be used such as welding or screwing.

Moreover, the four support components 220 included in the support stand 200 are disposed in positions corresponding to the four through-holes 60 in the chassis 21 of the organic EL panel unit 20, as illustrated in FIG. 8.

For example, upon performing various inspections on the organic EL panel unit 20, the engaging parts 222 of support components 220 are inserted into the four through-holes 60 disposed on the rear surface side of the organic EL panel unit 20.

More specifically, as illustrated in FIG. 9, the first hole 60a, which is a portion of the through-hole 60, is of a size that allows for insertion and removal of the engaging part 222 of the support component 220. Moreover, the second hole 60b, which is a portion of the through-hole 60, is of a size that causes the second hole 60b to engage the engaging part 222 inserted into the protrusion 21a through the first hole 60a (is of a size such that the engaging part 222 cannot be removed via the second hole 60b).

For example, considering one pair of the through-hole 60 and the support component 220, as illustrated in FIG. 10, the organic EL panel unit 20 is moved such that the engaging part 222 of the support component 220 is inserted into the protrusion 21a via the first hole 60a of the through-hole 60. Next, the organic EL panel unit 20 is moved downward, whereby the engaging part 222 of the support component 220 engages with the edge of the through-hole 60 (the second hole 60b). In other words, the engagement state between the engaging part 222 of the support component 220 and the through-hole 60 (the second hole 60b) is maintained by the weight of the organic EL panel unit 20.

Here, as illustrated in FIG. 9, for example, the through-hole 60 is formed in a shape that allows for insertion and removal of the engaging part 222 of the support component 220 and does not allow insertion of the shaft part 221.

Thus, since the engaging part 222 side end face of the shaft part 221 abuts the edge of the through-hole 60 (the first hole 60a) while the engaging part 222 of the support component 220 is inserted in the first hole 60a, movement of the engaging part 222 toward the organic EL panel 10 is restricted.

Since this, for example, prevents the engaging part 222 from interfering with the organic EL panel 10, damage to the organic EL panel 10 by the support component 220 can be prevented.

The organic EL panel unit 20 is supported by the support stand 200 as a result of the engagement state between the support component 220 and the through-hole 60 (the second hole 60b) being realized with four pairs of through-holes 60 and support components 220, as illustrated in FIG. 11, for example. Various inspections are performed on the organic EL panel unit 20 in this state.

Afterward, the engagement state between the four pairs of through-holes 60 and support components 220 (second holes 60b) can be released and the organic EL panel unit 20 can be removed from the support stand 200 by lifting up the organic EL panel unit 20.

In other words, so long as the organic EL panel unit 20 is not lifted up, the organic EL panel unit 20 is stably supported because the support components 220 cannot be removed from the through-holes 60 of the organic EL panel unit 20.

Note that the support component 220 according to this embodiment is formed by, for example, performing a cutting process on a round, metal rod, or screwing, welding, or bonding together a plurality of parts.

Moreover, for example, the support component 220 can be configured by screwing two nuts of different diameters onto a rod having threads on its outer surface such that the nuts are spaced apart from each other.

In other words, among the two nuts, the large diameter nut disposed in the middle of the rod functions as the shaft part 221, and the small diameter nut disposed at the end of the rod functions as the engaging part 222.

With this configuration, for example, the length of the support component 220 that can be inserted into the through-hole 60 can be easily adjusted.

Moreover, in this embodiment, a rectangular region defined by connecting the four through-holes 60 disposed on the rear surface side of the chassis 21 is disposed in the center region in the widthwise direction of the chassis 21 and offset downward in the vertical direction (z axis direction).

This is because the center of gravity of the organic EL panel unit 20 is located in the center region in the widthwise direction of the chassis 21 and offset downward in the vertical direction due to, for example, the layout of elements such as the power supply circuit. In other words, the positions of the four through-holes 60 are determined taking into consideration stability when the support stand 200 is supporting the organic EL panel unit 20.

Stated differently, the position of the one or more through-holes 60 disposed on the rear surface side of the chassis 21 may be, for example, determined to be anywhere on the protrusion 21a taking into consideration ease of inspection of the organic EL panel unit 20 and, for example, balance of the center of gravity of the organic EL panel unit 20.

### [1-4. Advantageous Effects, Etc.]

As described above, the image display device 1 according to this embodiment includes an organic EL panel unit 20.

Moreover, the organic EL panel unit 20 includes an organic EL panel 10 and a chassis 21 that is disposed on the rear surface side of the organic EL panel 10 and holds the organic EL panel 10. The chassis 21 includes a protrusion 21a that protrudes away from the organic EL panel 10 and has a through-hole 60 formed therethrough.

With this, for example, an element (the through-hole 60) for supporting the organic EL panel unit 20 in a standing state can be formed using a portion (the protrusion 21a) formed to strengthen the chassis 21. Consequently, an organic EL panel unit 20 that can easily be supported in a standing state and can be made thin is achievable.

Moreover, in this embodiment, the through-hole 60 is a hole that penetrates through a portion of the protrusion 21a, in a protruding direction of the protrusion 21a, and is formed to have, in a plan view, two ends in opposing locations having mutually different widths.

With this, the support component 220 can be inserted into and removed from the through-hole 60 freely, and reliability of the engagement between the support component 220 and the through-hole 60 (the edge of the through-hole 60) can be increased.

Moreover, in this embodiment, among the two ends in a plan view of the through-hole 60, the lower end is greater in width than the upper end.

More specifically, among the two ends in a plan view of the through-hole 60 according to this embodiment, the lower end is of a size that allows for insertion and removal of the support component 220, and the upper end is of a size that causes the upper end to engage the support component 220 inserted via the lower end.

With this, the engagement state between the support component 220 and the through-hole 60 can be maintained by, for example, the weight of the organic EL panel unit 20.

Note that the organic EL panel unit 20 may include a through-hole of a shape different from the shape illustrated in FIG. 9, for example.

Next, variations of the through-hole disposed in the organic EL panel unit 20 for supporting the organic EL panel unit 20 in a standing state Will be described focusing on the differences with the above embodiment.

### [2-1. Variation 1]

FIG. 12 illustrates the relationship between the sizes and shapes of a through-hole 61 according to Variation 1 of the embodiment and the support component 220.

In the through-hole 61 illustrated in FIG. 12, the end 61a, which is the lower end in a plan view, is of a shape that allows for insertion and removal of the support component 220, and the end 61b, which is the upper end, is of a size that causes the end 61b to engage the support component 220 inserted via the lower end 61a.

Moreover, a defining characteristic of the through-hole 61 according to Variation 1 is that it is formed to have a region that narrows in width from a first end 61a to a second end 61b among the two ends.

In other words, compared to the through-hole 60 according to the above embodiment, the boundary between the portion that allows for insertion and removal of the engaging part 222 of the support component 220 and the portion that restricts removal of the engaging part 222 the through-hole 61 is not clear. However, in the relatively wide end 61a, the through-hole 61 allows for the insertion and removal of the engaging part 222 of the support component 220, and in the relatively narrow end 61a, engagement with the engaging part 222 is possible.

In other words, stable support of the organic EL panel unit 20 is possible by inserting and engaging the support component 220 into and with the through-hole 61 formed in the protrusion 21a included in the chassis 21.

Note that the shape of the through-hole having a region that narrows in width from a first end to a second end among the two ends in a plan view of the through-hole may be, for example, a triangle or a trapezoid in addition to the example illustrated in FIG. 12. In other words, a through-hole having a triangular or trapezoidal plan view shape may be formed in the protrusion 21a as a through-hole for stably supporting the organic EL panel unit 20.

### [2-2. Variation 2]

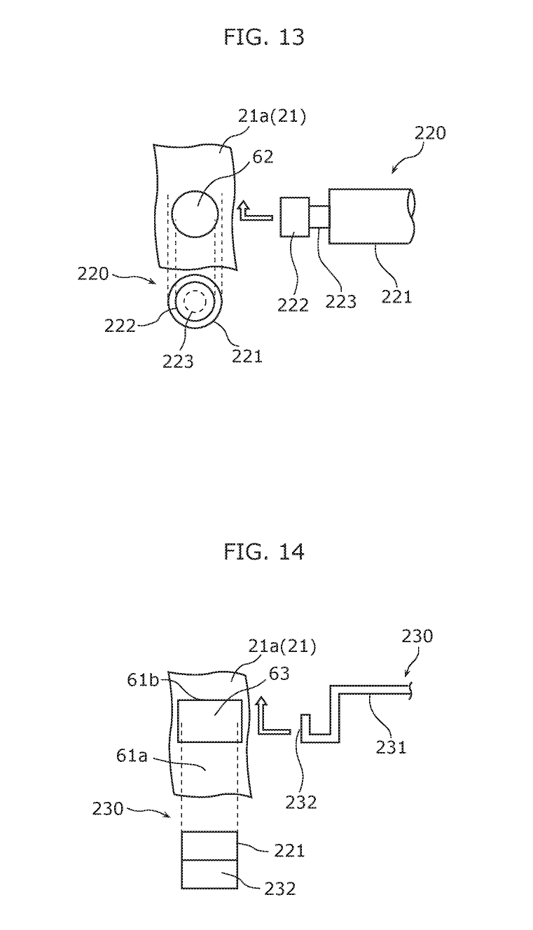

FIG. 13 illustrates the relationship between the sizes and shapes of a through-hole 62 according to Variation 2 of the embodiment and the support component 220.

The through-hole 62 illustrated in FIG. 13 has a plan view shape that is a circle of a size that allows for insertion and removal of the engaging part 222 and prevents insertion of the shaft part 221.

In other words, the through-hole 62 is a hole that is recognizable as a simple circular hole, rather than a hole of a shape in which a section that allows for insertion and removal of the engaging part 222 and a section that engages with the engaging part 222 are clearly distinguishable (i.e., a keyhole shape) like the through-hole 60 according to the above embodiment.

However, the support component 220 includes a small diameter part 223 between the engaging part 222 and the shaft part 221, whereby a step is formed between the engaging part 222 and the small diameter part 223. As such, when the organic EL panel unit 20 is moved downward after the engaging part 222 is inserted in the through-hole 62, the stepped part engages with the edge of the through-hole 62. In other words, stable support of the organic EL panel unit 20 by the support component 220 is possible.

Moreover, since the through-hole 62 is of a size that prohibits insertion of the shaft part 221, the engaging part 222 inserted via the through-hole 62 of the protrusion 21a can be prevented from interfering with the organic EL panel 10.

### [2-3. Variation 3]

FIG. 14 illustrates the relationship between the sizes and shapes of a through-hole 63 and a support component 230 according to Variation 3 of the embodiment.

The through-hole 63 illustrated in FIG. 14 has a rectangular plan view shape. In other words, the shape of the through-hole 63 in a plan view is not round like the through-hole 60 described in the above embodiment, but configured of straight lines only.

Moreover, the support component 230 has the shape of a bent elongated plate-like component to match the through-hole 63 shaped as described above. More specifically, the support component 230 includes an engaging part 232 and a shaft part 231.

Moreover, the through-hole 63 is of a size and shape that allows for insertion and removal of the engaging part 232, and the engaging part 232 has the shape of a hook.

In other words, as illustrated in FIG. 14, when the organic EL panel unit 20 is moved downward after the engaging part 232 is inserted in the through-hole 63, the engaging part 232 engages with the edge of the through-hole 63. In other words, stable support of the organic EL panel unit 20 by the support component 230 is possible.

Moreover, the through-hole 63 is of a size that prohibits insertion of the shaft part 231 when the support component 230 is inserted in the through-hole 63 and oriented perpendicular to the surface of the protrusion 21a on which the through-hole 63 is formed. In other words, when the organic EL panel unit 20 including the chassis 21 in which one or more through-holes 63 are formed is to be supported by the support stand 200 including the support component 230, the engaging part 232 inserted via the through-hole 63 and the organic EL panel 10 can be prevented from interfering with each other.

Moreover, since the edge of the through-hole 63 and the support component 230 are in contact with each other on a line parallel with the surface of the protrusion 21a in which the through-hole 63 is formed, the stability in the rotational direction of the organic EL panel unit 20 centered about the support component 230 increases, for example.

### [2-4. Variation 4]

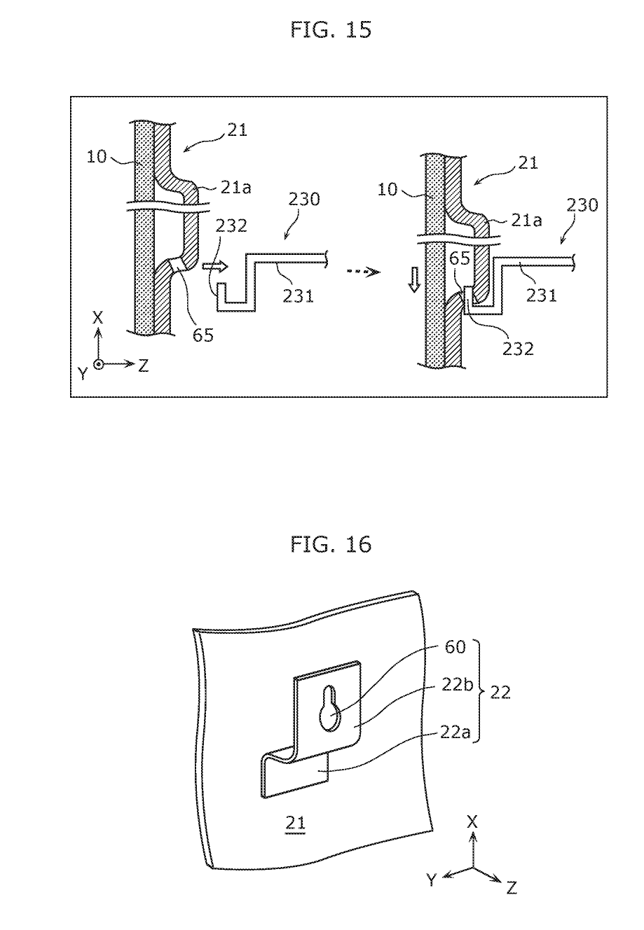

FIG. 15 is a partial cross sectional view of the support component 220 inserted in and engaging with a through-hole 65 according to Variation 4 of the embodiment.

The through-hole 65 illustrated in FIG. 15 differs from the through-hole 60 according to the above embodiment in that it is provided as a hole that protrudes through the protrusion 21a in a direction intersecting the protruding direction of the protrusion 21a.

More specifically, the through-hole 65 is provided as a hole protruding through the lower side surface of the protrusion 21a.

The support component 230 described in Variation 3 and illustrated in FIG. 14 is exemplified as the predetermined component that engages with this sort of through-hole 65.

In other words, as illustrated in FIG. 15, the organic EL panel unit 20 is moved to bring the tip end of the engaging part 232 of the support component 230 closer to the through-hole 65, and after the tip end of the engaging part 232 is located below the opening of the through-hole 65, the organic EL panel unit 20 is moved downward.

With this, the engaging part 232 of the support component 230 engages (fits with) the through-hole 65. In other words, the organic EL panel unit 20 is supported by the support component 230 while the engaging part 232 is hooked on the through-hole 65.

Moreover, in this state, a state in which the organic EL panel unit 20 is stably supported is maintained by the weight of the organic EL panel unit 20.

Moreover, since the edge of the through-hole 65 and the support component 230 are in contact with each other on a line parallel with the surface of the protrusion 21a in which the through-hole 65 is formed, the stability in the rotational direction of the organic EL panel unit 20 centered about the support component 230 increases, for example.

### [2-5. Variation 5]

FIG. 16 is a general external perspective view of a protrusion 22 according to Variation 5 of the embodiment.

The protrusion 22 illustrated in FIG. 16 differs from the protrusion 21a according to the above embodiment in that is included in chassis 21 as a component attached to the main body of the chassis 21.

More specifically, the protrusion 22 according to this variation includes a joining section 22a joined to the main body of the chassis 21, and a protruding section 22b that is connected to the joining section 22a and in which the through-hole 60 is formed.

Note that the protrusion 22 is made by, for example, forming the through-hole 60 by stamping a metal plate cut into a predetermined size, and then bending the metal plate.

Moreover, the protrusion 22 is attached to the main body of the chassis 21 by joining, using a method such as welding, bonding, or fastening with screws, the joining section 22a of the protrusion 22 to the main body of the chassis 21.

Such a protrusion 22 can be provided on the chassis 21 in the case that a bulge (a recess when viewed from the side on which the organic EL panel 10 is disposed), such as is illustrated in FIG. 2 and FIG. 3, for example, is not to be formed in the chassis 21 with a drawing process.

Alternatively, in the case that the bulge is formed in the chassis 21 by a drawing process but, for example, there is no bulge suitable for supporting the organic EL panel unit 20, such a protrusion 22 can be provided on the chassis 21.

For example, the organic EL panel unit 20 can be stably supported by the support stand 200 as a result of the chassis 21 including protrusions 22 in locations corresponding to the four support components 220 (for example, see FIG. 8) of the support stand 200.

In this way, the freedom with regard to where the one or more through-holes 60 can be located on the chassis 21 increases by providing the protrusion 22 including the through-hole 60 as a component separate from the main body of the chassis 21.

Moreover, since the plate-like component that is the main body of the chassis 21 is disposed between the through-hole 60 and the organic EL panel 10, the engaging part 222 of the support component 220 inserted in the through-hole 60 can be prevented from directly interfering with the organic EL panel 10, for example.

With this, for example, the projection amount of the protrusion 22 (the z axis direction height measured from the surface on which the protrusion 22 is disposed) can be minimized, which contributes to achieving a thin organic EL panel unit 20.

Note that the chassis 21 may include the protrusion 21a in which one or more through-holes 60 are formed and the protrusion 22 according to this variation. In other words, the through-hole 60 provided in the main body of the chassis 21 and the through-hole 60 provided in the protrusion 22 attached to the main body of the chassis 21 may both be employed.

Moreover, the protrusion 22 may have formed therethrough, in place of the through-hole 60, any one of the through-holes 61 through 63 and 65 according to the above Variations 1 through 4.

Moreover, two or more through-holes, such as the through-hole 60, may be formed through a single protrusion 22.

Moreover, the protrusion 22 may include a plurality of joining sections 22a. For example, joining sections 22a may be provided on both ends of a U-shaped protruding section 22b.

### 3. Other Embodiments

The above embodiment and variations are presented as examples of the techniques disclosed in the present application. However, the techniques of the present disclosure are not limited thereto; the techniques are also applicable to embodiments arrived at by making various modifications, interchanges, additions or omissions. The techniques are also applicable to new embodiments arrived at by combining various elements described in the above embodiment and variations.

Examples of other embodiments include the following.

For example, in the embodiment, four through-holes 60 are provided in the chassis 21. However, the chassis 21 may include at least one through-hole 60.

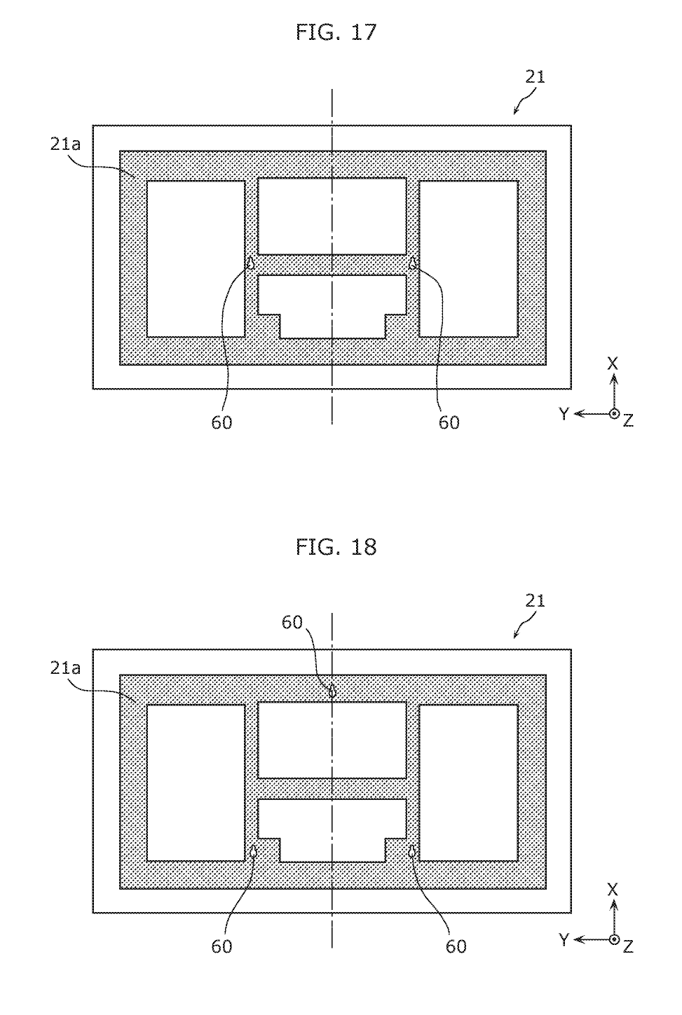

FIG. 17 illustrates one example of a positional arrangement of through-holes 60 when the chassis 21 includes two through-holes 60, and FIG. 18 illustrates one example of a positional arrangement of through-holes 60 when the chassis 21 includes three through-holes 60

For example, as illustrated in FIG. 17, the protrusion 21a of the chassis 21 may include two through-holes 60 formed a predetermined distance apart from each other.

In this case, for example, when the center of gravity of the organic EL panel unit 20 in the widthwise direction is located in the central region of the organic EL panel unit 20, the two through-holes 60 are arranged such that the midpoint between the two through-holes 60 is located in the center of the chassis 21 in the widthwise direction. Moreover, the support stand 200 includes two support components 220 arranged in positions where the support stand 200 can support the organic EL panel unit 20 using the two through-holes 60.

This makes stable support of the organic EL panel unit 20 by the support stand 200 possible.

Note that the positions in which the two through-holes 60 are arranged in a vertical direction are preferably located above the center of gravity of the organic EL panel unit 20 in the vertical direction. With this, for example, when the organic EL panel unit 20 is supported by the support stand 200, the organic EL panel unit 20 can be inhibited from leaning in the front-to-back direction (Z axis direction).

Moreover, as illustrated in FIG. 18, the protrusion 21a of the chassis 21 may include three through-holes 60.

In this case, for example, the three through-holes 60 are arranged in the protrusion 21a of the chassis 21 so as to be positioned at the points of an isosceles triangle. Moreover, the support stand 200 includes three support components 220 arranged in positions where the support stand 200 can support the organic EL panel unit 20 using the three through-holes 60. With this, stable support of the organic EL panel unit 20 is possible.

Moreover, since the organic EL panel unit 20 is supported at three points, when the organic EL panel unit 20 is supported by the support stand 200, the organic EL panel unit 20 can more reliably be inhibited from leaning in the front-to-back direction (Z axis direction).

Note that among the three through-holes 60 illustrated in FIG. 18, the support component 220 corresponding to the through-hole 60 located in the upper part and the widthwise central region of the protrusion 21a of the chassis 21 may be provided in a component that connects the top ends of the two columns 210 (see FIG. 8). With this, the support stand 200 does not interfere with the inspection of the circuit substrates 51 located in the central region of the chassis 21.

Moreover, although not illustrated in the drawings, the number of through-holes 60 formed in the protrusion 21a of the chassis 21 may be one. For example, by forming a single through-hole 60 in the upper part and the widthwise central region of the protrusion 21a of the chassis 21, support with a support stand 200 that includes only one support component 220 is possible.

Moreover, for example, when only one through-hole for supporting the organic EL panel unit 20 is formed in the chassis 21, a supporting structure the through-hole and the support component contact each other on a straight line, such as with the through-hole 63 and the support component 230 in Variation 3, can be employed. With this, stability upon supporting the organic EL panel unit 20 can be increased.

Moreover, the location in which the one or more through-holes 60 are arranged can be determined so as to be common among a plurality of organic EL panel units 20 of different screen sizes. With this, for example, a single, common support stand 200 can be used as a tool for supporting a plurality of organic EL panel units 20.

The supplementary recitations regarding the number and arrangement of the through-holes 60 also applies to the through-holes 61 through 63 and 65 according to the above Variations 1 through 4.

Moreover, the number of protrusions 22 in Variation 5 described above may be one or more. For example, the chassis 21 may include two protrusions 22 joined to the main body of the chassis 21 a predetermined distance apart from each other and, as a result, include two through-holes 60. In this case, for example, stable support of the organic EL panel unit 20 is possible by arranging the protrusions 22 such that the midpoint between the two through-holes 60 is located in the widthwise central region of the chassis 21.

The non-limiting embodiment has been described by way of example of the techniques of the present disclosure. To this extent, the accompanying drawings and detailed description are provided.

Thus, the elements set forth in the accompanying drawings and detailed description include not only components essential to solve the problems but also components unnecessary to solve the problems, for the purpose of illustrating the techniques. Thus, those unnecessary components should not be deemed essential due to the mere fact that they are described in the accompanying drawings and the detailed description.

The above embodiment is for providing an example of the techniques of the present disclosure, and thus various modifications, interchanges, additions and omissions are possible in the scope of the claims and equivalent scope thereof.

### INDUSTRIAL APPLICABILITY

The present disclosure is useful for image display devices where thinness is called for, and is applicable as an image display device, such as a television receiver, monitor display, digital signage, mobile device, tablet device, or table-top display device, and as an organic EL display device included in an image display device.

### REFERENCE SIGNS LIST

1 image display device
10 organic EL panel
20 organic EL panel unit
21 chassis
21a, 22 protrusion
22a joining section
22b protruding section
30 frame
40 back cover
50, 51 circuit substrate
60, 61, 62, 63, 65 through-hole
60a first hole
60b second hole
61a, 61b end
101 TFT substrate
110 pixel
110R, 110G, 110B sub pixel
111 bank
120 pixel circuit
130 organic EL element
131 anode
132 EL layer
133 cathode
140 gate wire
150 source wire
160 power supply wire
200 support stand
201 base
210 column
220, 230 support component
221, 231 shaft part
222, 232 engaging part
223 small diameter part

1. An organic EL display device, comprising:
an organic EL panel that displays an image on a front surface of the organic EL panel; and
a chassis that is disposed on a rear surface side of the organic EL panel and holds the organic EL panel,
wherein the chassis includes a protrusion that protrudes away from the organic EL panel, and the protrusion has a through-hole formed therethrough.

2. The organic EL display device according to claim 1, wherein
the through-hole is a hole that penetrates through a portion of the protrusion in a protruding direction of the protrusion, and is formed to have, in a plan view, two ends in opposing locations having mutually different widths.

3. The organic EL display device according to claim 2, wherein
among the two ends in a plan view of the through-hole, a lower end is greater in width than an upper end.

4. The organic EL display device according to claim 3, wherein
among the two ends in a plan view of the through-hole, the lower end is of a size that allows for insertion and removal of a predetermined component, and the upper end is of a size that causes the upper end to engage the predetermined component inserted via the lower end.

5. The organic EL display device according to claim 2, wherein
the through-hole includes a first hole and a second hole defined by an outwardly extending portion of an edge of the first hole, the first hole including a wider end among the two ends, and the second hole including a narrower end among the two ends.

6. The organic EL display device according to claim 2, wherein
the through-hole is formed to have a region that narrows in width from a first end to a second end among the two ends.

7. The organic EL display device according to claim 1, wherein
the protrusion is formed by stamping a portion of the chassis, the chassis being a plate-like component.

8. The organic EL display device according to claim 1, wherein
the protrusion includes two through-holes, each of which is the through-hole, formed a predetermined distance apart from each other.

9. The organic EL display device according to claim 1, wherein
the protrusion includes a joining section joined to a main body of the chassis, and a protruding section that is connected to the joining section and has the through-hole formed therethrough.

10. The organic EL display device according to claim 9, wherein
the chassis includes two protrusions, each of which is the protrusion, joined to the main body of the chassis a predetermined distance apart from each other and, as a result, includes two through-holes, each of which is the through-hole.

11. The organic EL display device according to claim 8, wherein
the two through-holes are arranged in the chassis such that a midpoint between the two through-holes is located in a widthwise center of the chassis.

12. A support stand that supports the organic EL display device according to claim 1 in a standing state, the support stand comprising:
a base;
a column standing on the base; and
a support component extending from the column in a direction intersecting a lengthwise direction of the column,
wherein the support component has an engaging part on a distal end opposite an end at the column, the engaging part engaging with an edge of the through-hole in a state in which the engaging part is inserted in the through-hole.

13. An image display device, comprising:
the organic EL display device according to claim 1; and
a back cover disposed on a rear surface side of the organic EL display device.
